(19) United States
(12) Patent Application Publication
(10) Pub. No.: US 2014/0217547 A1
(43) Pub. Date: Aug. 7, 2014

(54) SEMICONDUCTOR PACKAGE WITH AIR CORE INDUCTOR (ACI) AND MAGNETIC CORE INDUCTOR (MCI)

(71) Applicants: Adel A. Elsherbini, Chandler, AZ (US); Krishna Bharath, Chandler, AZ (US); Shamala A. Chickamenahalli, Chandler, AZ (US)

(72) Inventors: Adel A. Elsherbini, Chandler, AZ (US); Krishna Bharath, Chandler, AZ (US); Shamala A. Chickamenahalli, Chandler, AZ (US)

(21) Appl. No.: 13/997,042

(22) PCT Filed: Mar. 29, 2012
(86) PCT No.: PCT/US2012/031130

§ 371 Date: Jun. 21, 2013

(51) Int. Cl. H01L 49/02

(52) U.S. Cl. CPC H01L 28/10
USPC 257/531

(57) ABSTRACT

Semiconductor die packaged with air core inductors (ACIs) and magnetic core inductors (MCIs), or with multiple MCIs, are described. In a first example, a semiconductor package includes a semiconductor die, one or more air core inductors (ACIs) coupled to the semiconductor die, and one or more magnetic core inductors (MCIs) coupled to the semiconductor die. In a second example, a semiconductor package includes a semiconductor die, a first magnetic core inductor (MCI) coupled to the semiconductor die and having a first saturation current, and a second MCI coupled to the semiconductor die and having a second, different, saturation current.

### TECHNICAL FIELD

Embodiments of the invention are in the field of semiconductor packages and, in particular, semiconductor die packaged with air core inductors (ACIs) and magnetic core inductors (MCIs), or with multiple MCIs.

### BACKGROUND

Today's consumer electronics market frequently demands complex functions requiring very intricate circuitry. Scaling to smaller and smaller fundamental building blocks, e.g. transistors, has enabled the incorporation of even more intricate circuitry on a single die with each progressive generation. Semiconductor packages are used for protecting an integrated circuit (IC) chip or die, and also to provide the die with an electrical interface to external circuitry. With the increasing demand for smaller electronic devices, semiconductor packages are designed to be even more compact and must support larger circuit density. For example, some semiconductor packages now use a coreless substrate, which does not include the thick resin core layer commonly found in conventional substrates. Furthermore, the demand for higher performance devices results in a need for an improved semiconductor package that enables a thin packaging profile and low overall warpage compatible with subsequent assembly processing.

On the other hand, although scaling is typically viewed as a reduction in size, the addition of functionality in a given space is also considered. However, structural issues may arise when attempting to package semiconductor die with additional functionality also housed in the package. For example, the addition of packaged inductors may add functionality, but ever decreasing space availability in a semiconductor package may provide obstacles to adding such functionality.

### BRIEF DESCRIPTION OF THE DRAWINGS

FIG. 1 illustrates a standard magnetic core inductor (MCI) voltage regulator (VR) model.

FIG. 2A is a plot of ripple current (in Amps) as a function of time (in nanoseconds) for different air core inductor (ACI) sizes, in accordance with an embodiment of the present invention.

FIG. 2B is a plot of overall inductor loss (in %) as a function of duty cycle (in %) when the performance is optimized for a wide range of duty cycles, in accordance with an embodiment of the present invention.

FIG. 2C is a plot of overall inductor loss (in %) as a function of duty cycle (in %) when the performance is optimized for low duty cycles, in accordance with an embodiment of the present invention.

FIG. 3A illustrates a circuit implementation for combining air core inductors (ACIs) with magnetic core inductors (MCIs), in accordance with an embodiment of the present invention.

FIG. 3B illustrates another circuit implementation for combining air core inductors (ACIs) with magnetic core inductors (MCIs), in accordance with another embodiment of the present invention.

FIG. 4 illustrates a cross-sectional view of a semiconductor die packaged with an air core inductor (ACI) and a magnetic core inductor (MCI), in accordance with an embodiment of the present invention.

FIG. 5A illustrates a plan view of a base layer of a semiconductor package, in accordance with an embodiment of the present invention.

FIG. 5B illustrates a plan view of a magnetic core inductor (MCI) layout, in accordance with an embodiment of the present invention.

FIG. 5C illustrates a circuit implementation for combining air core inductors (ACIs) with magnetic core inductors (MCIs), in accordance with an embodiment of the present invention.

FIG. 6A illustrates a cross-sectional view of a coupling of the ACIs and MCIs of FIGS. 5A and 5B, in accordance with an embodiment of the present invention.

FIG. 6B illustrates an angled plan view of a coupling of the ACIs and MCIs of FIGS. 5A and 5B, in accordance with an embodiment of the present invention.

FIG. 7A illustrates a circuit implementation for combining multiple MCIs, in accordance with an embodiment of the present invention.

FIG. 7B is a plot of minimum overall inductor loss (in %) as a function of overall area (in mm²) for the efficiency at 50% duty cycle when using fixed width MCIs, compared to using multiple width MCIs, in accordance with an embodiment of the present invention.

FIG. 8 is a schematic of a computer system, in accordance with an embodiment of the present invention.

### DESCRIPTION OF THE EMBODIMENTS

Semiconductor die packaged with air core inductors (ACIs) and magnetic core inductors (MCIs), or with multiple MCIs, are described. In the following description, numerous specific details are set forth, such as packaging architectures and material regimes, in order to provide a thorough understanding of embodiments of the present invention. It will be apparent to one skilled in the art that embodiments of the present invention may be practiced without these specific details. In other instances, well-known features, such as integrated circuit design layouts, are not described in detail in order to not unnecessarily obscure embodiments of the present invention. Furthermore, it is to be understood that the various embodiments shown in the Figures are illustrative representations and are not necessarily drawn to scale.

One or more embodiments of the present inventions are directed at efficiency improvement and area reduction of nonlinear magnetic core inductors in integrated voltage regulators (IVRs) which may include MCIs or nonlinear magnetic inductors packaged with a semiconductor die, e.g., in a bumpless build-up layer (BBUL) package, in a cored substrate, or in a coreless substrate. Some embodiments include a semiconductor die packaged with both one or more ACIs and one or more MCIs.

Air core inductors typically require large form semiconductor packages, and possibly cored packages. As scaling and die shrinking is performed with each generation, package scaling is often required to provide ever smaller form factors. However, the reduction in package size makes inclusion of ACIs difficult since a smaller package means a smaller inductor which can lead to increased losses for the ACIs. Nonetheless, power management is trending towards the use of IVRs without a full understanding of the scalability of IVR components. In the near future, the package core area is expected to decrease by approximately 50% with each generation. Unfortunately, ACIs cannot scale by the same factor while maintaining the same performance. Predictions for IVRs performance based on ACIs show approximately 25-40% increase in inductor losses per generation.

Accordingly, the use of MCIs is currently being investigated. MCIs may offer comparable performance to ACIs in a much smaller volume through the use of high permeability materials (e.g., magnetic materials). However, MCIs may suffer from magnetic saturation effects. Magnetic saturation effects may lead to one or more detriments, such as, but not limited to, limiting the maximum achievable IVR efficiency, forcing the use of certain MCI topologies which renders the efficient operating region smaller and significantly increases the complexity of the IVR control circuitry (IVR controller) design, and requiring large MIM capacitors at the output. Furthermore, negatively coupled MCI designs may also suffer from high losses at low output voltages.

MCIs are small but have high magnetic fields inside the magnetic material. The small size and high magnetic fields can lead to magnetic saturation which may cause high ripple currents that significantly reduces the efficiency of the MCI. Such an effect may limit the use of MCIs in many power delivery applications requiring large direct current (DC) and alternating current (AC) currents. Through the use of negatively coupled inductors, the DC magnetic fields inside the magnetic core may be partially cancelled, leaving the AC current ripple as the primary limitation on the inductor size. By increasing the inductance, the AC current ripple may be decreased at the expense of lower efficiency and significantly more complex controller design. Furthermore, negatively coupled MCIs may have high coupling factors. Such high coupling factors often require a large output metal-insulator-metal (MIM) capacitor in order to achieve a stable controller design. However, incorporation of such a large output capacitor would require a large number of MIM layers in the silicon process to support scaling. In addition, the high coupling factors used in MCI voltage regulators (VRs) can result in significantly degraded performance at low output voltages due to the high current ripple at low output-to-input voltage ratios. Standard MCI design is typically based on using standard cell inductors all having the same saturation currents. For a fixed operating point, this may limit the maximum efficiency as a function of area.

Embodiments of the present invention address some of above issues with standard MCI IVRs. In accordance with a first embodiment of the present invention, MCIs are combined with small ACIs. The required inductance for such ACIs may be an order of magnitude smaller than standard ACI designs and thus may not present a scaling challenge. In one embodiment, a small ACI is sufficient to prevent negative consequences of MCIs going into saturation. Such a combination of MCIs and ACIs may allow for a VR controller design that is significantly simplified compared to standard coupled MCIs FIVRs. Additionally, a corresponding output MIM capacitor may be decreased in size by up to 43%. The resulting combination may allow for the use of fewer MIM capacitor layers at a given process node, reducing the wafer cost by approximately 1-2%. Furthermore, compared to fully coupled MCI designs, the embodiments described herein may significantly improve the VR efficiency and reduce associated thermal losses by up to approximately 35% at duty cycles farther from 50%. Such improvements may enable maximization of idle and turbo mode efficiencies. Accordingly, performance under turbo mode may be improved and battery life increased in mobile applications.

In accordance with a second embodiment of the present invention, different inductors having different saturation currents are combined. In one such embodiment, the combination provides an approach for achieving the maximum VR efficiency out of a given area using MCIs. The VR efficiency may be further improved the VR by an additional 1-2 percentage points. In a third embodiment, the above two described embodiments are combined to achieve efficiency improvement by up to approximately 5 percentage points and to reduce the output capacitor area while remaining scalable.

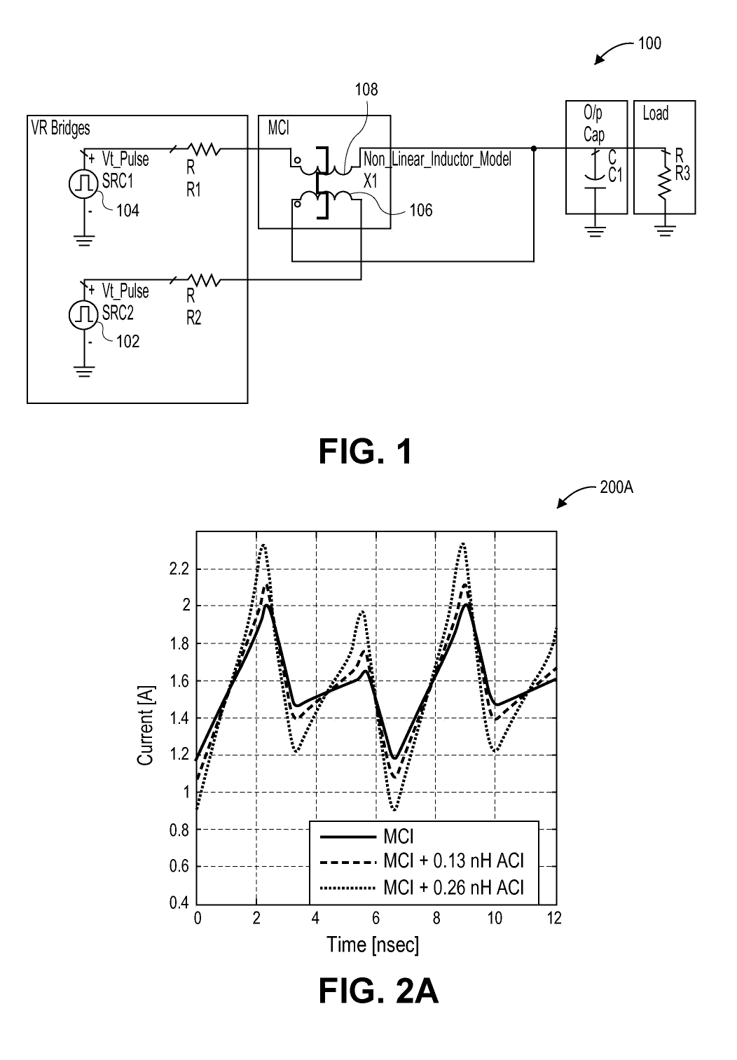

For instructional purposes, FIG. 1 illustrates a standard MCI VR model. Referring to FIG. 1, a voltage regulator (VR) 100 includes two transistor bridges 102, 104 operating with a certain phase delay between them at a certain switching frequency. The two transistor bridges 102, 104 are connected to magnetic core inductors (MCIs) 106, 108 such that the two MCI inductors are negatively coupled. Because of the opposing directions of the direct current (DC) current flow, the magnetic core does not saturate due to the DC current. Nevertheless, the magnetic core may saturate due to the alternating current (AC) currents which have a certain phase delay between them and add up cumulatively inside the core. When the magnetic core saturates, the current ripple may become large which can lead to excessive losses. To avoid saturation, the inductance may be increased such that the current ripple is reduced below the saturation current. However, such an approach may increase the losses since the larger inductor can translate to higher DC and AC losses as well.

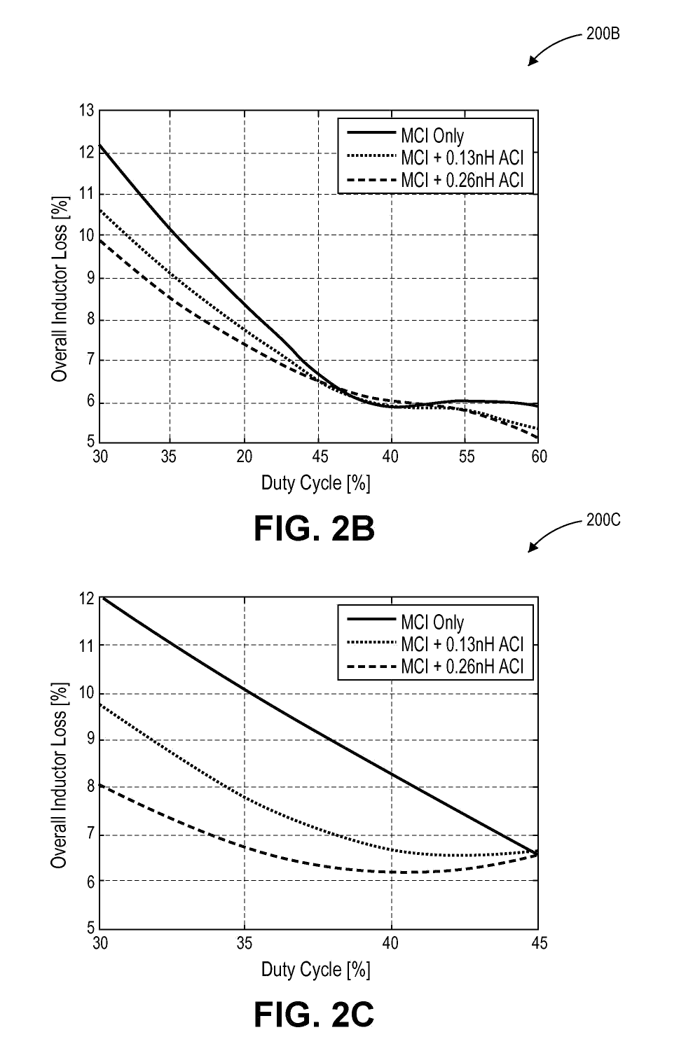

As mentioned briefly above, in one embodiment, an MCI is combined with a small ACI. In a specific such embodiment, when the MCI saturates, its inductance drops to less than approximately 10% of the non-saturated value which can cause the current to increase significantly. However, by using a small ACI with an inductance approximately 10% of the MCI unsaturated inductance, the peak current may be reduced significantly. A reduction in peak current can provide a reduced AC loss, as shown in FIG. 2A. FIG. 2A is a plot 200A of ripple current (in Amps) as a function of time (in nanoseconds) for different ACI sizes. The reduced AC loss results in significant improvement in the efficiency at low and high duty cycles by approximately 1-3 percentage points (e.g., reducing total losses by up to 22%), as shown in FIG. 2B. FIG. 2B is a plot 200B of overall inductor loss (in %) as a function of duty cycle (in %), e.g., efficiency vs. duty cycles, when the performance is optimized for a wide range of duty cycles (e.g., server applications). As well, the benefits are realized with little to no expense in the total area since the ACIs may be implemented as part of the routing from a semiconductor die to the VR, as described below.

Furthermore, in an embodiment, the above combination can be optimized for mobile applications in order to increase the overall efficiency at low duty cycles by approximately 4 percentage points (e.g., approximately 33% reduction in losses), as shown in FIG. 2C. FIG. 2C is a plot 200C of overall inductor loss (in %) as a function of duty cycle (in %) when the performance is optimized for low duty cycles (e.g., mobile applications or when using on-die switches to short a section of the MCI at low duty cycles). In an embodiment, the above approach can be implemented in a reconfigurable fashion by shorting a section of the MCI at low duty cycles using power gate switches on either an associated circuit die or the MCI die, thus achieving efficiency improvements and loss reduction of up to approximately 35% over the entire range of output voltages.

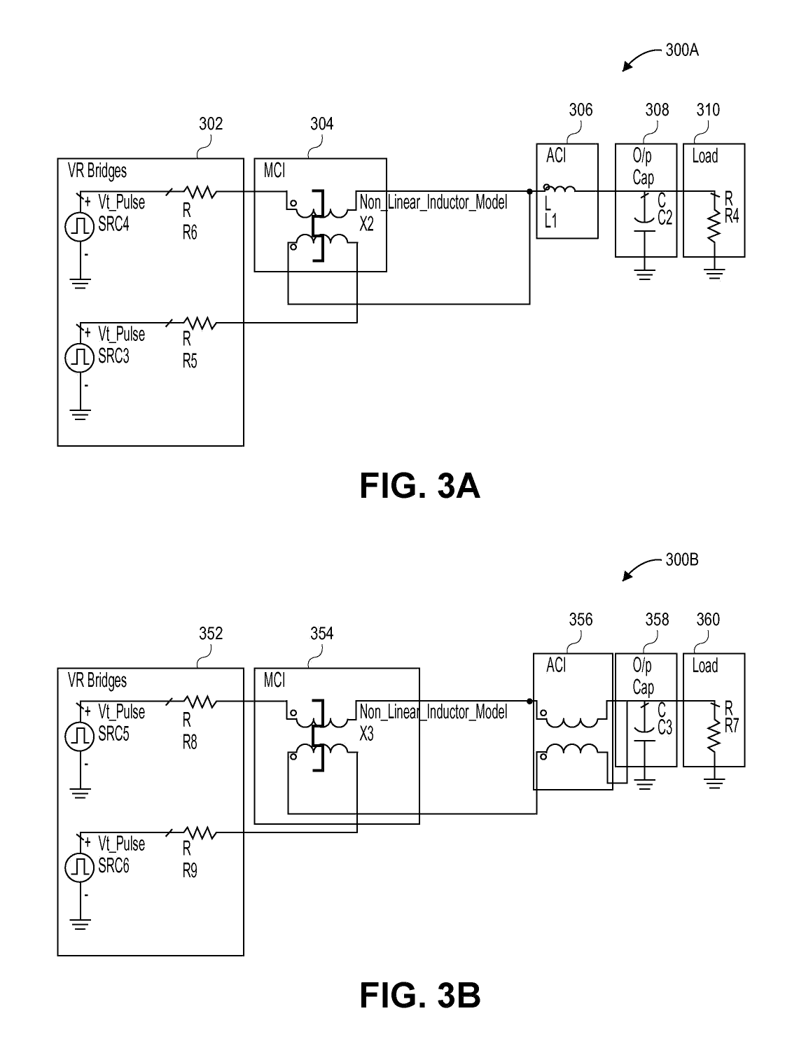

Several options may exist for including an ACI inside of an MCI circuit topology. For example, in a first embodiment, FIG. 3A illustrates a circuit implementation for combining ACIs with MCIs. Referring to FIG. 3A, a circuit 300A includes voltage regulator (VR) bridges 302, a magnetic core inductor (MCI) region 304, and a single uncoupled air core inductor (ACI) 306 connected to the output of the coupled MCI region 304. A capacitor (cap) 308 and load 310 are also included. In another example, in a second embodiment, FIG. 3B illustrates another circuit implementation for combining ACIs with MCIs. Referring to FIG. 3B, a circuit 300A includes voltage regulator (VR) bridges 352, a magnetic core inductor (MCI) region 354, and two positively coupled air core inductors (ACIs) 356 connected to the output of the coupled MCI region 354. A capacitor (cap) 358 and load 360 are also included.

Both implementations 300A and 300B may provide comparable performance and selection between the two may be made based substantially on layout considerations. An additional advantage to implementations 300A and 300B may be that the ACI will increase the transient inductance of the MCI by an additional approximately 36-72% which can simplify the VR controller design and enable using an output capacitor that is approximately 32-43% smaller compared to standard MCI VRs. A smaller output capacitor may reduce the wafer cost by approximately 1-2% depending on the MIM capacitance density at the technology node.

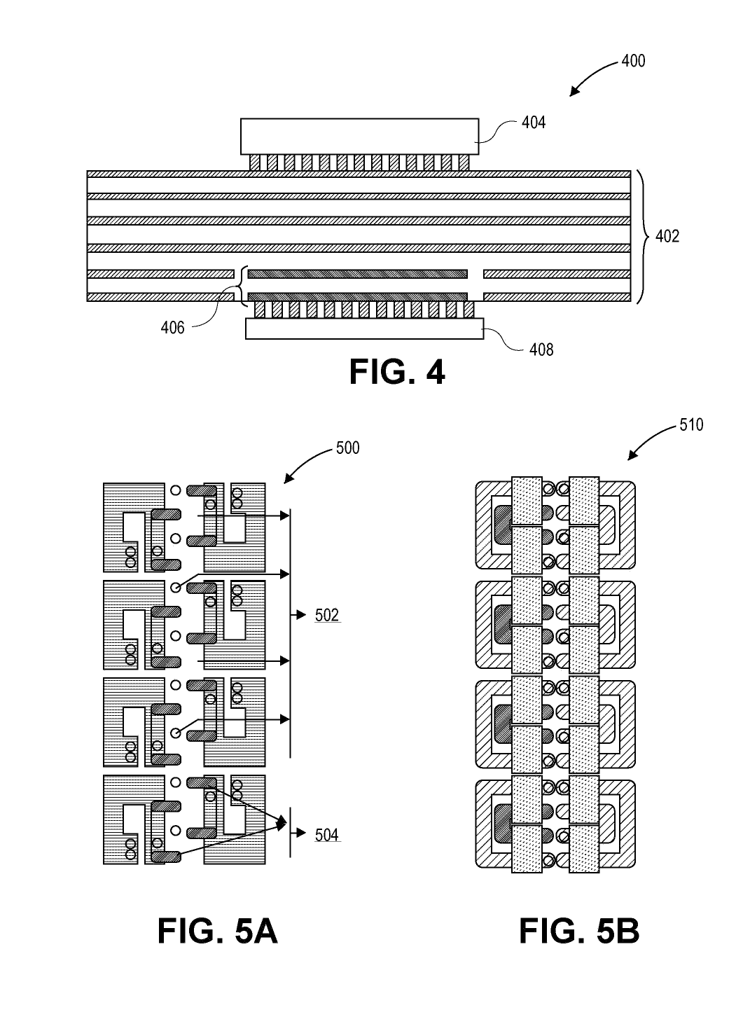

A variety of options may exist for packaging semiconductor dies with both MCIs and ACIs. For example, in a first embodiment, an MCI die is placed in an interposer configuration between a semiconductor circuit die and a package substrate. In a second embodiment, an MCI die is included on a top side buildup of a package. In a third embodiment, an MCI die is included as a surface mount assembled on the back side of a package, e.g., in the cavity of the package. This third option is illustrated with respect to FIG. 4. FIG. 4 illustrates a cross-sectional view of a semiconductor die packaged with an ACI and an MCI, in accordance with an embodiment of the present invention. Referring to FIG. 4, a semiconductor apparatus 400 includes a semiconductor package 402 with a central processing unit (CPU) 404 disposed thereon. An air core inductor (ACI) 406 is included in the semiconductor package 402. A magnetic core inductor (MCI) die 408 is surface mounted on the semiconductor package 402, opposing the CPU 404.

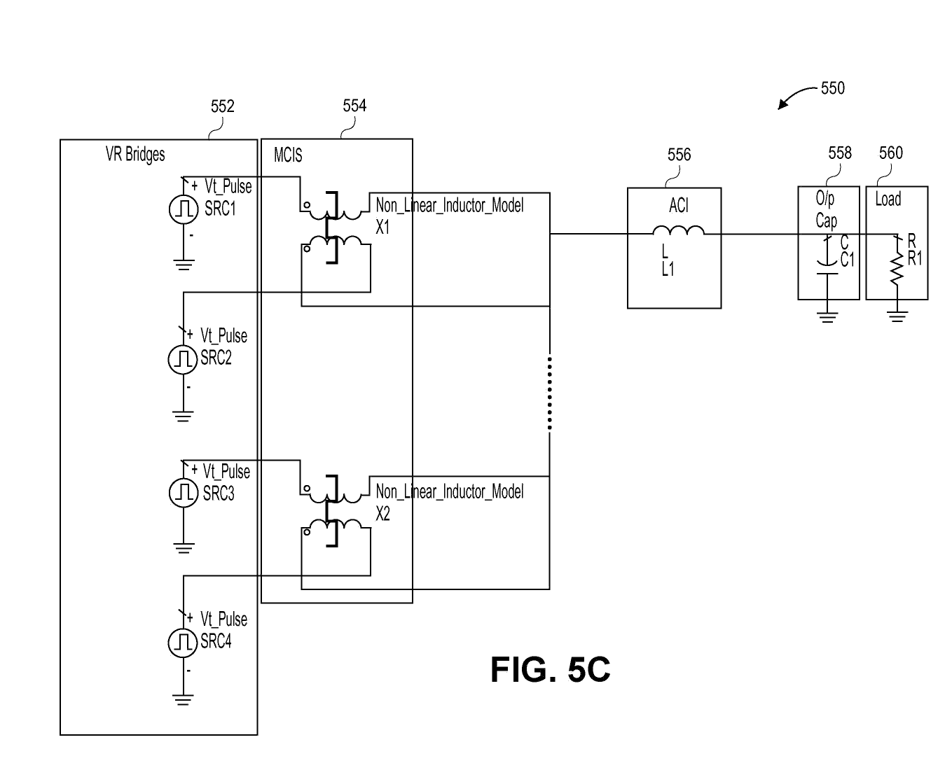

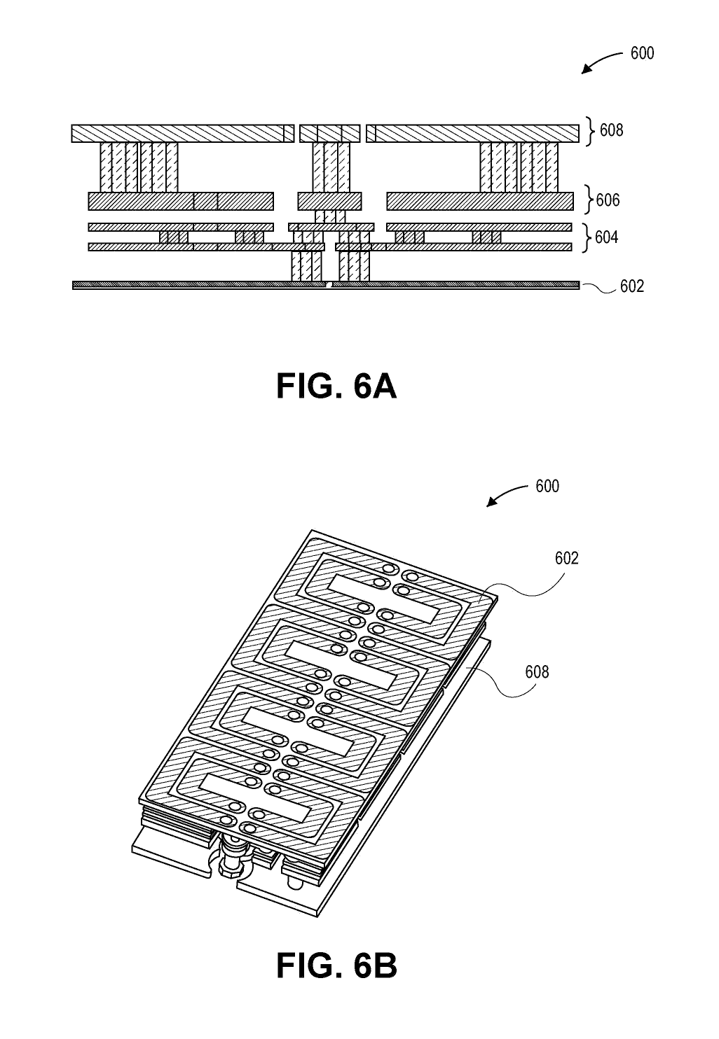

FIG. 5A and 5B illustrate an ACI layout showing connections from bridges to MCI, in accordance with an embodiment of the present invention. Specifically, FIG. 5A illustrates a plan view of a base layer of a semiconductor package, while FIG. 5B illustrates a plan view of a magnetic core inductor (MCI) layout. Referring to FIG. 5A, a base layer 500 includes interconnects 502 from bridges to MCIs. Also included are outputs 504 of the MCI coupled to the ACI. There are eight individual ACIs as shown. Referring to FIG. 5B, a magnetic core inductor 510 includes eight individual inductors, as shown. In an embodiment, the ACIs are sized assuming a projected core area of approximately 2.5 mm². The connections from the bridge transistors on a CPU semiconductor circuit die to the MCIs are shown centered between the ACIs. The other terminals of the MCIs are then connected to the ACI, which in turn may be routed to the top side build-up of a package (e.g., the package of FIG. 4) to distribute output voltage (Vₒᵤₜ) to the CPU, as described in greater detail below in association with FIGS. 6A and 6B. It is to be understood that, although shown for illustrative purposes, each of the ACI and the MCI can have more than or fewer than eight individual inductors.

It is also to be understood that the number of individual inductors for the MCI and the ACI need not be the same. Although both are shown with eight in FIGS. 5A/5B, in another embodiment, FIG. 5C illustrates a circuit implementation for combining ACIs with MCIs. Referring to FIG. 5C, a circuit 550 includes voltage regulator (VR) bridges 552, a magnetic core inductor (MCI) region 554 including two MCIs, and a single air core inductor (ACI) 556 connected to the output of the coupled MCI region 554. A capacitor (cap) 558 and load 560 are also included.

FIG. 6A illustrates a cross-sectional view of a coupling of the ACIs and MCIs of FIGS. 5A and 5B, in accordance with an embodiment of the present invention. Referring to FIG. 6A, a portion of a semiconductor apparatus 600 includes an MCI level 602. Routing layer 604 coupled the MCI level 602 with an ACI level 606. An output voltage (Vout) layer 608 is routed to the ACI level 606. FIG. 6B illustrates an angled plan view of a coupling of the ACIs and MCIs of FIGS. 5A and 5B, in accordance with an embodiment of the present invention. Referring to FIG. 6B, the MCI level 602 and the Vout layer 608 can be seen.

In accordance with another embodiment of the present invention, MCIs with different saturation currents are included in a semiconductor package. For example, wider MCIs have higher saturation currents and lower loss. However, due to the size of MCIs, they may not fit within a desired confined area. Narrower MCIs have lower saturation currents and higher loss, but their area requirements are relatively small. By combining different size MCIs, in one embodiment, an optimum efficiency may be achieved for a given area. Thus, a design may be based on using smaller higher saturation currents MCIs to provide current limiting at saturation similar to those of the above described ACIs.

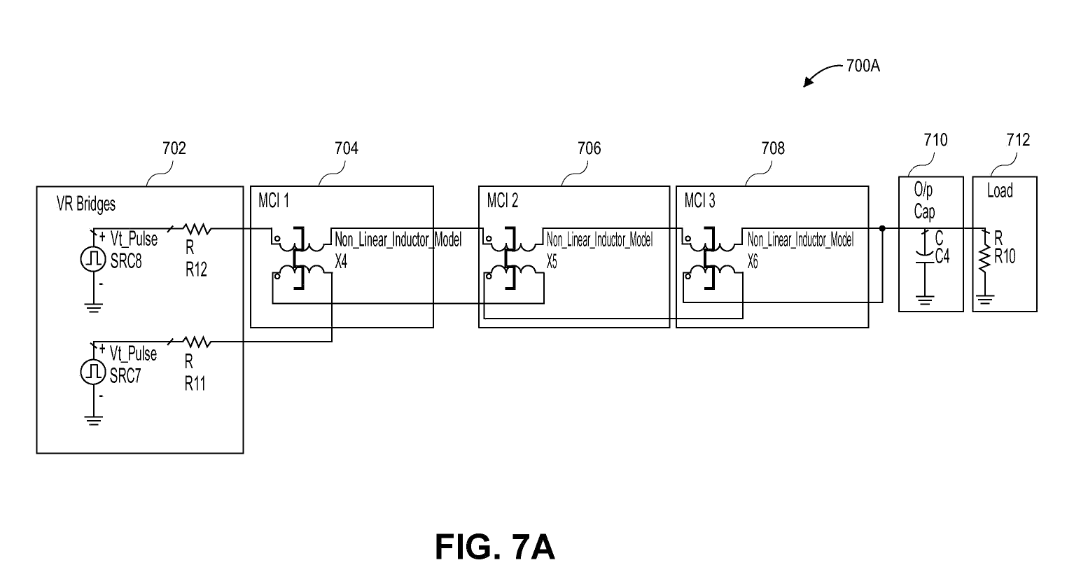

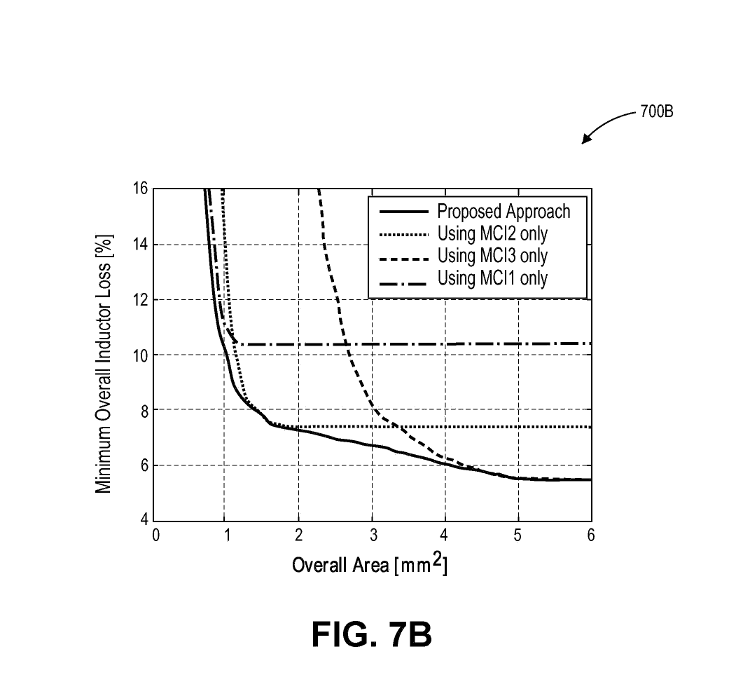

As an example, in an embodiment, FIG. 7A illustrates a circuit implementation for combining multiple MCIs. Referring to FIG. 7A, a circuit 700A includes voltage regulator (VR) bridges 702, a first magnetic core inductor (MCI) region 704, a second magnetic core inductor (MCI) region 706 and a third magnetic core inductor (MCI) region 708. A capacitor (cap) 710 and load 712 are also included. The first magnetic core inductor (MCI) region 704 has the lowest saturation current and the smallest area, while the third magnetic core inductor (MCI) region 708 has the highest saturation current and largest area. In an embodiment, by combining different inductors a maximum possible efficiency may be achieved for a given area, as compared to having few discrete options as, shown in FIG. 7B. FIG. 7B is a plot 700B of minimum overall inductor loss (in %) as a function of overall area (in mm²) for the efficiency at 50% duty cycle when using fixed width MCIs, compared to using multiple width MCIs. The latter may utilize all available area to achieve the maximum efficiency. For example, the above described approach may provide an additional efficiency improvement by approximately 1-2% (e.g., an additional 20% reduction in losses).

As mentioned above, a semiconductor die packaged with ACIs and an MCI die, or with multiple MCIs, may be housed in a variety of packaging options. One such option is housing in a coreless substrate formed by a BBUL process. BBUL is a processor packaging technology that is bumpless since it does not use the usual small solder bumps to attach the silicon die to the processor package wires. It has build-up layers since it is grown or built-up around the silicon die. Some semiconductor packages now use a coreless substrate, which does not include the thick resin core layer commonly found in conventional substrates. In an embodiment, as part of the BBUL process, electrically conductive vias and routing layers are formed above an active side of the semiconductor die using a semi-additive process (SAP) to complete remaining layers. In an embodiment, an external contact layer is formed. In one embodiment, an array of external conductive contacts is a ball grid array (BGA). In other embodiments, the array of external conductive contacts is an array such as, but not limited to, a land grid array (LGA) or an array of pins (PGA).

In an embodiment, a substrate is a coreless substrate since a panel is used to support packaging of a semiconductor die through to formation of an array of external conductive conducts. The panel is then removed to provide a coreless package for the semiconductor die. Accordingly, in an embodiment, the term “coreless” is used to mean that the support upon which the package was formed for housing a die is ultimately removed at the end of a build-up process. In a specific embodiment, a coreless substrate is one that does not include a thick core after completion of the fabrication process. As an example, a thick core may be one composed of a reinforced material such as is used in a motherboard and may include conductive vias therein. It is to be understood that die-bonding film may be retained or may be removed. In either case, inclusion or exclusion of a die-bonding film following removal of the panel provides a coreless substrate. Still further, the substrate may be considered a coreless substrate because it does not include a thick core such as a fiber reinforced glass epoxy resin.

A packaged semiconductor die may, in an embodiment, be a fully embedded and surrounded semiconductor die. As used in this disclosure, “fully embedded and surrounded” means that all surfaces of the semiconductor die are in contact with an encapsulating film (such as a dielectric layer) of substrate, or at least in contact with a material housed within the encapsulating film. Said another way, “fully embedded and surrounded” means that all exposed surfaces of the semiconductor die are in contact with the encapsulating film of a substrate.

A packaged semiconductor die may, in an embodiment, be a fully embedded semiconductor die. As used in this disclosure, “fully embedded” means that an active surface and the entire sidewalls of the semiconductor die are in contact with an encapsulating film (such as a dielectric layer) of a substrate, or at least in contact with a material housed within the encapsulating film. Said another way, “fully embedded” means that all exposed regions of an active surface and the exposed portions of the entire sidewalls of the semiconductor die are in contact with the encapsulating film of a substrate. However, in such cases, the semiconductor die is not “surrounded” since the backside of the semiconductor die is not in contact with an encapsulating film of the substrate or with a material housed within the encapsulating film. In a first embodiment, a back surface of the semiconductor die protrudes from the global planarity surface of the die side of a substrate. In a second embodiment, no surface of the semiconductor die protrudes from the global planarity surface of the die side of a substrate.

In contrast to the above definitions of “fully embedded and surrounded” and “fully embedded,” a “partially embedded” die is a die having an entire surface, but only a portion of the sidewalls, in contact with an encapsulating film of a substrate (such as a coreless substrate), or at least in contact with a material housed within the encapsulating film. In further contrast, a “non-embedded” die is a die having at most one surface, and no portion of the sidewalls, in contact with an encapsulating film of a substrate (such as a coreless substrate), or in contact with a material housed within the encapsulating film.

In an embodiment, a substrate includes an encapsulant layer. In an embodiment, a semiconductor package for housing a semiconductor die packaged with ACIs and an MCI die, or with multiple MCIs, includes a foundation substrate at the land side of the substrate. For example, where the semiconductor die is part of a hand-held device such as a smart phone embodiment or a hand-held reader embodiment, the foundation substrate may be a motherboard, an external shell such as the portion an individual touches during use, or both the motherboard and an external shell such as the portion an individual touches during use.

In another aspect, a semiconductor die packaged with ACIs and an MCI die, or with multiple MCIs, are housed in a core of a substrate. In one such embodiment, the semiconductor die and the MCI die are embedded within the same core material. The packaging processes may, in an embodiment, be performed on a carrier. A carrier, such as a panel, may be provided having a plurality of cavities disposed therein, each sized to receive a semiconductor die and MCI die pair. During processing, identical structures may be mated in order to build a back-to-back apparatus for processing utility. Consequently, processing throughput is effectively doubled.

For example, a panel may include 1000 recesses on either side, allowing for fabrication of 2000 individual packages from a single panel. The panel may include an adhesion release layer and an adhesive binder. A cutting zone may be provided at each end of the apparatus for separation processing. A backside of a semiconductor die and MCI die pair (e.g. at the backside of the CTE-engineer die portion) may be bonded to the panel with a die-bonding film. Encapsulating layers may be formed by a lamination process. In another embodiment, one or more encapsulation layers may be formed by spinning on and curing a dielectric upon a wafer-scale array of apparatuses.

In an embodiment, one or more of the above described semiconductor packages housing a semiconductor die and an MCI die are paired with other packages following the packaging process, e.g., the coupling of a packaged memory die with a package logic die. In an example, connections between two or more individually packaged die may be made post BBUL fabrication by using thermal compression bonding (TCB) processing. In another embodiment, more than one both die are embedded in the same package. For example, in one embodiment, a packaged semiconductor die and MCI die pair further includes a secondary stacked die. The first die may have one or more through-silicon vias disposed therein (TSV die). The second die may be electrically coupled to the TSV die through the one or more through-silicon vias. The apparatus may also include a coreless substrate. In one embodiment, all die are embedded in the coreless substrate.

Thus, embodiments of the present invention enable fabrication of packaged semiconductor die co-packaged with ACIs and MCIs, or multiple MCIs. Such embodiments may provide benefits such as, but not limited to, cost reduction. The unique combination of components and techniques described herein may be fully compatible with conventional equipment toolsets. In an embodiment, such apparatuses provide integrated voltage regulators (IVRs) implementing magnetic core inductors to improve the efficiency by up to approximately 4 percentage points (e.g., reducing losses by approximately 30%) and reducing the required MIM capacitor area by up to approximately 43% resulting in cost reduction of approximately 2-4% per wafer. In an embodiment, a minimum o/p capacitor size for a stable compensator depends on the coupling factor of the inductors. For example, the capacitor may be designed such that the compensated bandwidth is <N*fs/6. There is a square root dependence for compensated bandwidth, so minimum o/p capacitor decreases with the number of stages. In one embodiment, the minimum number of stages is 4 for MCIs and 2 for ACIs.

In an embodiment, a magnetic core inductor is an inductor that includes a magnetic core made of a ferromagnetic or ferrimagnetic material, such as iron or ferrite, to increase the inductance. In an embodiment, an air core inductor is an inductor that does not use a magnetic core made of a ferromagnetic material. The term refers to coils wound on plastic, ceramic, or other nonmagnetic forms, as well as those that actually have air inside the windings.

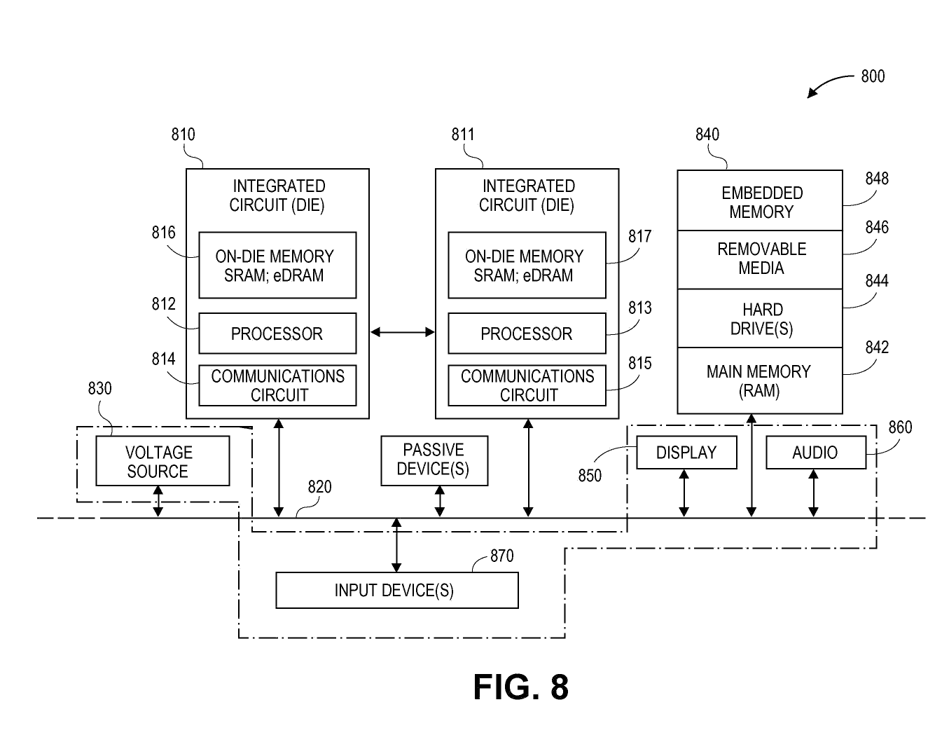

FIG. 8 is a schematic of a computer system 800, in accordance with an embodiment of the present invention. The computer system 800 (also referred to as the electronic system 800) as depicted can embody a semiconductor die packaged with both ACIs and MCIs according to any of the several disclosed embodiments and their equivalents as set forth in this disclosure. The computer system 800 may be a mobile device such as a netbook computer. The computer system 800 may be a mobile device such as a wireless smart phone. The computer system 800 may be a desktop computer. The computer system 800 may be a hand-held reader.

In an embodiment, the electronic system 800 is a computer system that includes a system bus 820 to electrically couple the various components of the electronic system 800. The system bus 820 is a single bus or any combination of busses according to various embodiments. The electronic system 800 includes a voltage source 830 that provides power to the integrated circuit 810. In some embodiments, the voltage source 830 supplies current to the integrated circuit 810 through the system bus 820.

The integrated circuit 810 is electrically coupled to the system bus 820 and includes any circuit, or combination of circuits according to an embodiment. In an embodiment, the integrated circuit 810 includes a processor 812 that can be of any type. As used herein, the processor 812 may mean any type of circuit such as, but not limited to, a microprocessor, a microcontroller, a graphics processor, a digital signal processor, or another processor. In an embodiment, the processor 812 includes a semiconductor die packaged with both ACIs and MCIs, as disclosed herein. In an embodiment, SRAM embodiments are found in memory caches of the processor. Other types of circuits that can be included in the integrated circuit 810 are a custom circuit or an application-specific integrated circuit (ASIC), such as a communications circuit 814 for use in wireless devices such as cellular telephones, smart phones, pagers, portable computers, two-way radios, and similar electronic systems. In an embodiment, the processor 810 includes on-die memory 816 such as static random-access memory (SRAM). In an embodiment, the processor 810 includes embedded on-die memory 816 such as embedded dynamic random-access memory (eDRAM).

In an embodiment, the integrated circuit 810 is complemented with a subsequent integrated circuit 811. Useful embodiments include a dual processor 813 and a dual communications circuit 815 and dual on-die memory 817 such as SRAM. In an embodiment, the dual integrated circuit 810 includes embedded on-die memory 817 such as eDRAM.

In an embodiment, the electronic system 800 also includes an external memory 840 that in turn may include one or more memory elements suitable to the particular application, such as a main memory 842 in the form of RAM, one or more hard drives 844, and/or one or more drives that handle removable media 846, such as diskettes, compact disks (CDs), digital variable disks (DVDs), flash memory drives, and other removable media known in the art. The external memory 840 may also be embedded memory 848 such as the first die in an embedded TSV die stack, according to an embodiment.

In an embodiment, the electronic system 800 also includes a display device 850, an audio output 860. In an embodiment, the electronic system 800 includes an input device such as a controller 870 that may be a keyboard, mouse, trackball, game controller, microphone, voice-recognition device, or any other input device that inputs information into the electronic system 800. In an embodiment, an input device 870 is a camera. In an embodiment, an input device 870 is a digital sound recorder. In an embodiment, an input device 870 is a camera and a digital sound recorder.

As shown herein, the integrated circuit 810 can be implemented in a number of different embodiments, including a semiconductor die packaged with both ACIs and MCIs according to any of the several disclosed embodiments and their equivalents, an electronic system, a computer system, one or more methods of fabricating an integrated circuit, and one or more methods of fabricating an electronic assembly that includes a semiconductor die packaged with both ACIs and MCIs according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed semiconductor die packaged with both ACIs and MCIs embodiments and their equivalents. A foundation substrate may be included, as represented by the dashed line of FIG. 8. Passive devices may also be included, as is also depicted in FIG. 8.

Embodiments of the present invention include semiconductor die packaged with ACIs and MCIs, or with multiple MCIs.

In an embodiment, a semiconductor package includes a semiconductor die, one or more air core inductors (ACIs) coupled to the semiconductor die, and one or more magnetic core inductors (MCIs) coupled to the semiconductor die.

In one embodiment, one or more of the ACIs is coupled directly to one or more of the MCIs.

In one embodiment, the semiconductor package further includes a capacitor coupled to one of the ACIs, and a load coupled to the capacitor. The one or more ACIs, the one or more MCIs, the capacitor and the load form a portion of an integrated voltage regulator for the semiconductor die.

In one embodiment, the one or more ACIs have a total number of ACIs, the one or more MCIs have a total number of MCIs, and the total number of MCIs is equal to the total number of ACIs.

In one embodiment, the one or more ACIs have a total number of ACIs, the one or more MCIs have a total number of MCIs, and the total number of MCIs is different from the total number of ACIs.

In an embodiment, a semiconductor package includes a substrate, a semiconductor die coupled to the substrate, one or more air core inductors (ACIs) formed in the substrate and coupled to the semiconductor die, and a magnetic core inductor die coupled to the substrate. The magnetic core inductor die includes one or more magnetic core inductors (MCIs) coupled to the semiconductor die.

In one embodiment, the substrate is a bumpless build-up layer (BBUL) substrate.

In one embodiment, the semiconductor die and the magnetic core inductor die are housed in a core of the substrate.

In one embodiment, the substrate is a coreless substrate.

In one embodiment, one or more of the ACIs is coupled directly to one or more of the MCIs.

In one embodiment, the semiconductor package further includes a capacitor coupled to one of the ACIs, and a load coupled to the capacitor. The one or more ACIs, the one or more MCIs, the capacitor and the load form a portion of a fully integrated voltage regulator (FIVR) for the semiconductor die.

In one embodiment, the one or more ACIs have a total number of ACIs, the one or more MCIs have a total number of MCIs, and the total number of MCIs is equal to the total number of ACIs.

In one embodiment, the one or more ACIs have a total number of ACIs, the one or more MCIs have a total number of MCIs, and the total number of MCIs is different from the total number of ACIs.

In an embodiment, a semiconductor package includes a semiconductor die, a first magnetic core inductor (MCI) coupled to the semiconductor die and having a first saturation current, and a second MCI coupled to the semiconductor die and having a second, different, saturation current.

In one embodiment, the first MCI is coupled directly to the second MCI.

In one embodiment, the semiconductor package further includes a capacitor coupled to the second MCI, and a load coupled to the capacitor. The first and second MCIs, the capacitor and the load form a portion of an integrated voltage regulator (IVR) for the semiconductor die.

In one embodiment, the semiconductor package further includes a third MCI coupled directly to both the first and second MCIs, the third MCI having a saturation current different from, and between, the saturation currents of the first and second MCIs.

In an embodiment, a semiconductor package includes a substrate, a semiconductor die coupled to the substrate, and a magnetic core inductor die coupled to the substrate. The magnetic core inductor die includes a first magnetic core inductor (MCI) coupled to the semiconductor die and having a first saturation current, and a second MCI coupled to the semiconductor die and having a second, different, saturation current.

In one embodiment, the substrate is a bumpless build-up layer (BBUL) substrate.

In one embodiment, the semiconductor die and the magnetic core inductor die are housed in a core of the substrate.

In one embodiment, the substrate is a coreless substrate.

In one embodiment, the first MCI is coupled directly to the second MCI.

In one embodiment, the semiconductor package further includes a capacitor coupled to the second MCI, and a load coupled to the capacitor. The first and second MCIs, the capacitor and the load form a portion of a fully integrated voltage regulator (FIVR) for the semiconductor die.

In one embodiment, the magnetic core inductor die further includes a third MCI coupled directly to both the first and second MCIs. The third MCI has a saturation current different from, and between, the saturation currents of the first and second MCIs.

What is claimed is:

1. A semiconductor package, comprising:
a semiconductor die;
one or more air core inductors (ACIs) coupled to the semiconductor die; and
one or more magnetic core inductors (MCIs) coupled to the semiconductor die.

2. The semiconductor package of claim 1, wherein one or more of the ACIs is coupled directly to one or more of the MCIs.

3. The semiconductor package of claim 1, further comprising:
a capacitor coupled to one of the ACIs; and
a load coupled to the capacitor, wherein the one or more ACIs, the one or more MCIs, the capacitor and the load form a portion of an integrated voltage regulator (IVR) for the semiconductor die.

4. The semiconductor package of claim 1, wherein the one or more ACIs have a total number of ACIs, the one or more MCIs have a total number of MCIs, and the total number of MCIs is equal to the total number of ACIs.

5. The semiconductor package of claim 1, wherein the one or more ACIs have a total number of ACIs, the one or more MCIs have a total number of MCIs, and the total number of MCIs is different from the total number of ACIs.

6. A semiconductor package, comprising:
a substrate;
a semiconductor die coupled to the substrate;
one or more air core inductors (ACIs) formed in the substrate and coupled to the semiconductor die; and
a magnetic core inductor die coupled to the substrate, the magnetic core inductor die comprising one or more magnetic core inductors (MCIs) coupled to the semiconductor die.

7. The semiconductor package of claim 6, wherein the substrate is a bumpless build-up layer (BBUL) substrate.

8. The semiconductor package of claim 7, wherein the semiconductor die and the magnetic core inductor die are housed in a core of the substrate.

9. The semiconductor package of claim 7, wherein the substrate is a coreless substrate.

10. The semiconductor package of claim 6, wherein one or more of the ACIs is coupled directly to one or more of the MCIs.

11. The semiconductor package of claim 6, further comprising:
a capacitor coupled to one of the ACIs; and
a load coupled to the capacitor, wherein the one or more ACIs, the one or more MCIs, the capacitor and the load form a portion of an integrated voltage regulator (IVR) for the semiconductor die.

12. The semiconductor package of claim 6, wherein the one or more ACIs have a total number of ACIs, the one or more MCIs have a total number of MCIs, and the total number of MCIs is equal to the total number of ACIs.

13. The semiconductor package of claim 6, wherein the one or more ACIs have a total number of ACIs, the one or more MCIs have a total number of MCIs, and the total number of MCIs is different from the total number of ACIs.

14. A semiconductor package, comprising:
a semiconductor die;
a first magnetic core inductor (MCI) coupled to the semiconductor die and having a first saturation current; and
a second MCI coupled to the semiconductor die and having a second, different, saturation current.

15. The semiconductor package of claim 14, wherein the first MCI is coupled directly to the second MCI.

16. The semiconductor package of claim 14, further comprising:
a capacitor coupled to the second MCI; and
a load coupled to the capacitor, wherein the first and second MCIs, the capacitor and the load form a portion of a fully integrated voltage regulator (FIVR) for the semiconductor die.

17. The semiconductor package of claim 14, further comprising:
a third MCI coupled directly to both the first and second MCIs, the third MCI having a saturation current different from, and between, the saturation currents of the first and second MCIs.

18. A semiconductor package, comprising:
a substrate;
a semiconductor die coupled to the substrate; and
a magnetic core inductor die coupled to the substrate, the magnetic core inductor die comprising:
a first magnetic core inductor (MCI) coupled to the semiconductor die and having a first saturation current; and
a second MCI coupled to the semiconductor die and having a second, different, saturation current.

19. The semiconductor package of claim 18, wherein the substrate is a bumpless build-up layer (BBUL) substrate.

20. The semiconductor package of claim 19, wherein the semiconductor die and the magnetic core inductor die are housed in a core of the substrate.

21. The semiconductor package of claim 19, wherein the substrate is a coreless substrate.

22. The semiconductor package of claim 18, wherein the first MCI is coupled directly to the second MCI.

23. The semiconductor package of claim 18, further comprising:
a capacitor coupled to the second MCI; and
a load coupled to the capacitor, wherein the first and second MCIs, the capacitor and the load form a portion of an integrated voltage regulator (IVR) for the semiconductor die.

24. The semiconductor package of claim 14, the magnetic core inductor die further comprising:
a third MCI coupled directly to both the first and second MCIs, the third MCI having a saturation current different from, and between, the saturation currents of the first and second MCIs.
